(19) United States
(12) Patent Application Publication
(10) Pub. No.: US 2006/0044772 A1
(43) Pub. Date: Mar. 2, 2006

(54) Semiconductor module

(75) Inventor: Taiki Miura, Ibo-gun (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/022,765

(22) Filed: Dec. 28, 2004

(30) Foreign Application Priority Data
Aug. 31, 2004 (JP) 2004-253140

(51) Int. Cl. H05K 7/12

(52) U.S. Cl. 361/767

(57) ABSTRACT

A semiconductor module comprises a mount member. A first semiconductor chip having an upper surface and a lower surface is mounted via flip chip bonding on the mount member with the upper surface faced to the mount member. The upper surface includes a drain electrode and a gate formed therein and the lower surface includes a source electrode formed therein. A second semiconductor chip having an upper surface and a lower surface is mounted via flip chip bonding on the mount member with the upper surface faced to the mount member. The upper surface includes a source electrode and a gate formed therein and the lower surface includes a drain electrode formed therein. An electrically conductive and thermally radiative member is disposed to electrically connect the source electrode of the first semiconductor chip with the drain electrode of the second semiconductor chip and cover the lower surfaces of the semiconductor chips. A resinous member is provided to seal the first and second semiconductor chips in a single package.

### CROSS-REFERENCE TO RELATED APPLICATION

This application is based upon and claims the benefit of priority from the prior Japanese Patent Application No. 2004-253140, filed on Aug. 31, 2004; the entire contents of which are incorporated herein by reference.

### BACKGROUND OF THE INVENTION

1. Field of the Invention

The present invention relates to a semiconductor module such as a multi-chip module.

2. Description of the Related Art

The use of a CPU in information communications instruments such as a personal computer strongly requires a lower voltage, a larger current and a faster response. The lower voltage serves to reduce power consumed in the CPU. The larger current is effective to achieve quick operation of the CPU and improve the integration density thereof. The faster response is advantageous to quickly respond to a variation in CPU-controlled load. In recent years, a CPU tends to have an operating voltage lowered to about 1 V, an operating current elevated over 50 A, and a clock frequency exceeding 1 GHz.

A buttery or an AC source does not serve to supply power directly to the CPU and the CPU-controlled loads. The power from the buttery or the like is once converted at a power source provided in an information communications instrument to have a desired voltage and then supplied to the CPU and so forth. As the information communications instrument is downsized and mobilized, a range of voltages fed to the power source is widened and an extended buttery-drive time is required. Therefore, there is a need for a high-efficiency power source.

The CPU and each load include respective power sources therein to prevent power uselessly supplied to the CPU and each load to reduce total power consumed in the entire system of the information communications instrument. A description is given to a notebook PC, for example, which includes a power source for a CPU, a power source for a LCD screen, and a power source for a hard disc. Equipment of a plurality of power sources increases the area occupied by the power sources in the entire system and accordingly requires downsizing of the power sources. Thus, there is a need for a high-efficiency, downsized power source.

A DC-DC converter is described herein as an example of the power source. The DC-DC converter is a device operative to convert a certain voltage DC current into a different voltage DC current. As the DC-DC converter has a high efficiency and can be downsized, it has been utilized as a power source fabricated in a small information communications instrument (such as a notebook PC and a cell phone).

Among conventional high-power DC-DC converters, there is a synchronous rectifying non-insulated step-down DC-DC converter. It comprises an N-channel power MOSFET (Metal Oxide Semiconductor Field Effect Transistor), a SBD (Schottky Barrier Diode), a PWM (Pulse Width Modulation) control IC, an inductor, a coil, and so forth. These components are packaged individually and such packaged components are attached on a printed circuit board.

For downsizing such the step-down DC-DC converter, it may be preferable to elevate the operating frequency in CPU, for example, to downsize the inductor and the coil. For providing the step-down DC-DC converter with a higher efficiency, it is effective to achieve a lower on-resistance and a faster switching operation as well as reduction in parasitic capacitance and inductance on wires in the power MOSFET.

A power device for use in a power source, such as the power MOSFET, may produce heat due to power losses caused through the on-resistance and the switching operation. Therefore, it is required to use any suitable means to radiate the heat. For example, JP-A 14-217416 discloses in paragraph 0043 and FIGS. 5-6 a semiconductor module, which comprises two power semiconductor chips mounted on a lead frame and packaged in one. In this case, heat is radiated through the lead frame.

In this way, the semiconductor module is required to have the ability of heat radiation. It is also required to reduce impedance in the semiconductor module for achievement of a high-efficiency power source as described above. It is further required to downsize the semiconductor module itself to downsize the power source.

### BRIEF SUMMARY OF THE INVENTION

In an aspect of the present invention, a semiconductor module comprises a mount member. A first semiconductor chip having an upper surface and a lower surface is mounted via flip chip bonding on the mount member with the upper surface faced to the mount member. The upper surface includes a drain electrode and a gate formed therein, and the lower surface includes a source electrode formed therein. A second semiconductor chip having an upper surface and a lower surface is mounted via flip chip bonding on the mount member with the upper surface faced to the mount member. The upper surface includes a source electrode and a gate formed therein, and the lower surface includes a drain electrode formed therein. An electrically conductive and thermally radiative member is disposed to electrically connect the source electrode of the first semiconductor chip with the drain electrode of the second semiconductor chip and cover the lower surfaces of the semiconductor chips. A resinous member is provided to seal the first and second semiconductor chips in a single package.

In another aspect of the present invention, a semiconductor module comprises a mount member. A first and a second semiconductor chips each having an upper surface and a lower surface are mounted via flip chip bonding on the mount member with the upper surface faced to the mount member. The upper surface includes a first main electrode and a gate formed therein, and the lower surface includes a second main electrode formed therein. An electrically conductive and thermally radiative member is disposed to electrically connect the second main electrode of the first semiconductor chip with the second main electrode of the second semiconductor chip and cover the lower surfaces of the semiconductor chips. A resinous member is provided to seal the first and second semiconductor chips in a single package. The first semiconductor chip includes a first semiconductor substrate of a first conduction type made contact with the second main electrode, a first semiconductor region of the first conduction type located on the first semiconductor substrate, a second semiconductor region of a second conduction type formed in the first semiconductor region and made contact with the first main electrode, a third semiconductor region of the second conduction type formed in the first semiconductor region and made conductive to the second semiconductor region through a channel formed under the gate, and a short electrode arranged to short between the first semiconductor region and the third semiconductor region. The second semiconductor chip includes a second semiconductor substrate of the second conduction type made contact with the second main electrode, a fourth semiconductor region of the second conduction type located on the second semiconductor substrate and having a current path in a vertical direction, a fifth semiconductor region of the second conduction type made contact with the first main electrode, and a sixth semiconductor region of the first conduction type, in which a channel is formed under the gate to make the fourth semiconductor region conductive to the fifth semiconductor region therethrough.

### BRIEF DESCRIPTION OF THE DRAWINGS

FIG. 1 is a plan view of a semiconductor module according to the embodiment;

FIG. 2 is a cross-sectional view taken along II(a)-II(b) line in FIG. 1;

FIG. 3 is a cross-sectional view taken along III(a)-III(b) line in FIG. 1;

FIG. 4 is a cross-sectional view of part of a power MOS chip (an example of the first semiconductor chip) according to the embodiment;

FIG. 5 is a cross-sectional view of part of a power MOS chip (an example of the second semiconductor chip) according to the embodiment;

FIG. 6 is a circuit diagram of a DC-DC converter according to the embodiment;

FIG. 7 is a timing chart of signals input to the power MOS chips 5 and 7 in FIG. 6;

FIG. 8 is a cross-sectional view of a semiconductor device according to a first comparative example;

FIG. 9 is a cross-sectional view of a semiconductor device according to the embodiment;

FIG. 10 is a plan view of a semiconductor module according to a second comparative example;

FIG. 11 is a cross-sectional view taken along XI(a)-XI(b) line in FIG. 10;

FIG. 12 shows a current path in the semiconductor module according to the second comparative example;

FIG. 13 shows a current path in the semiconductor device according to the embodiment;

FIG. 14 illustrates an electrically conductive and thermally radiative member positioned in the z-direction during fabrication of the semiconductor module according to the second comparative example;

FIG. 15 shows the electrically conductive and thermally radiative member obliquely mounted in the second comparative example; and

FIG. 16 illustrates an electrically conductive and thermally radiative member positioned in the z-direction during fabrication of the semiconductor module according to embodiment.

### DETAILED DESCRIPTION OF THE INVENTION

The embodiments of the present invention will now be described with reference to the drawings. In the figures illustrative of the embodiments, the same parts as those denoted with the reference numerals in the figure already described are denoted with the same reference numerals to omit their duplicated description. The semiconductor module according to the embodiment is exemplified as a multi-chip module that includes two power MOS chips and a driving IC chip all sealed in a single package. This module serves as part of a DC-DC converter.

The power MOS chip may comprise a FET that includes a gate insulator film composed of silicon oxide though the present invention is not limited to this example. For example, it is applicable to a power MIS (Metal Insulator Semiconductor) chip comprising a FET that includes a gate insulator film composed of an insulator other than silicon oxide (such as a high dielectric film). The power MOS chip is an example of the power MIS chip. The semiconductor module according to the embodiment is employed for the DC-DC converter though the present invention is not limited to this example. For example, it can be employed in a signal transmission circuit in a digital instrument such as an audio instrument.

Structure of Semiconductor Module

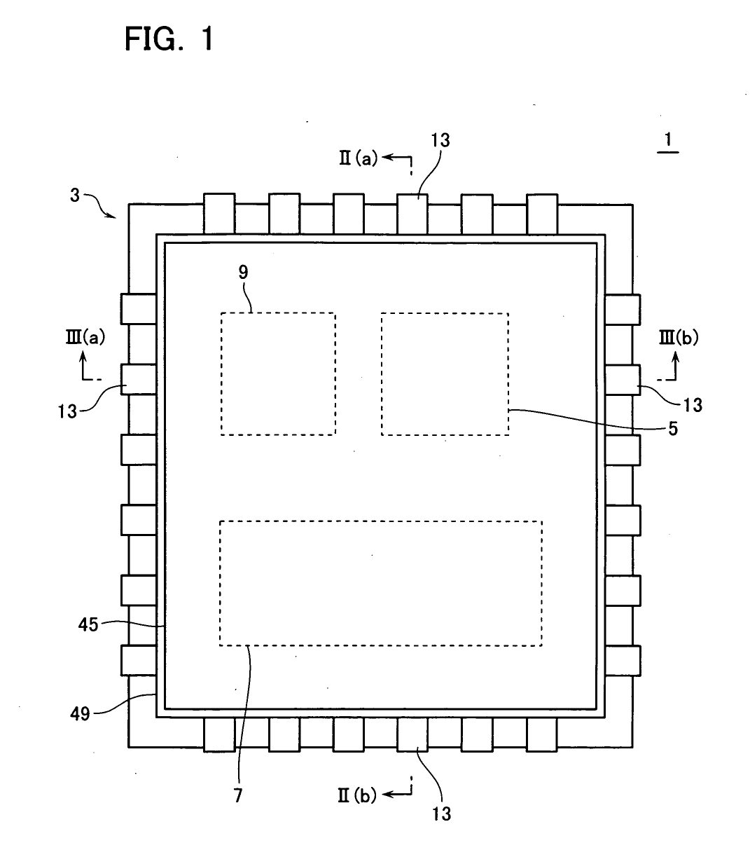

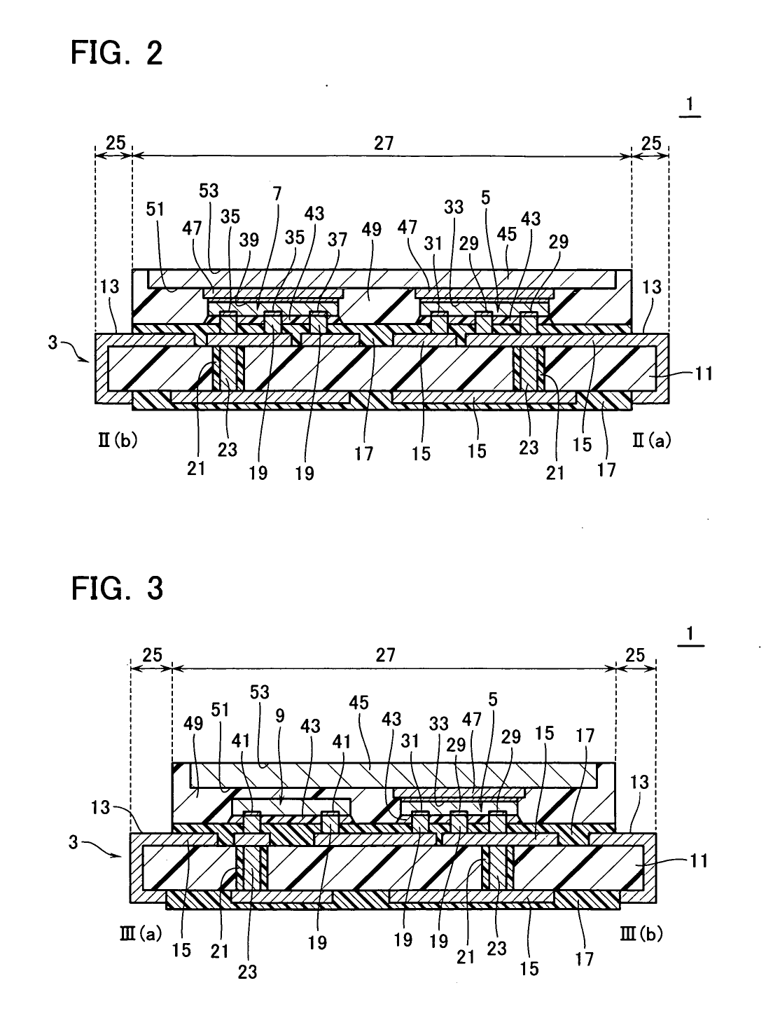

A structure of the semiconductor module according to the embodiment is described with reference to FIGS. 1-3. FIG. 1 is a plan view of the semiconductor module 1 according to the embodiment, FIG. 2 is a cross-sectional view taken along II(a)-II(b) line in FIG. 1, and FIG. 3 is a cross-sectional view taken along III(a)-III(b) line in FIG. 1.

The semiconductor module 1 comprises a mount member 3 such as a printed circuit board, and two power MOS chips 5, 7 and a driving IC chip 9, which are mounted on the mount member. The power MOS chip 5 is an example of the first semiconductor chip, and the power MOS chip 7 is an example of the second semiconductor chip. These semiconductor chips are also referred to as power switching device chips. The driving IC chip 9 serves to drive gates of MOSFETs formed in the power MOS chips 5 and 7. The mount member 3 is not limited to the printed circuit board but may be a lead frame composed of, for example, copper or the like.

The mount member 3 includes a square resinous plate 11. The rim of the resinous plate 11 is provided with many external terminals 13, which extend from one surface of the resinous plate 11 around sides to the other surface. Wires 15 are formed on both surfaces of the resinous plate 11 and connected to the external terminals 13. The external terminals 13 and the wires 15 are composed of a conductor such as a copper film.

Insulator (such as solder resist) films 17 are formed on both surfaces of the resinous plate 11 to cover the wires 15. The insulator films 17 are not employed to cover the external terminals 13 and have openings on portions of the wires 15 connected to the chips 5, 7 and 9. Bumps 19 composed of, for example, solder are screen-printed in these openings.

A number of through-holes are formed through the resinous plate 11. An insulator film 21 such as a silicon oxide film is formed on the inner side of the through-hole. A conductor film 23 is buried in the through-hole. The buried conductor film 23 serves to electrically connect the wires 15 on both surfaces of the resinous plate 11 with each other.

The mount member 3 is divided into two regions. One is an external terminal region 25 located at the rim of the mount member 3 and employed to form the external terminals 13 therein. Another is a mount region 27 located more inwardly than the external terminal region 25 and employed to form the wires 15 therein. The power MOS chip 5 and so forth are mounted on the mount region 27.

The power MOS chips 5, 7 and the driving IC chip 9 are mounted via flip chip bonding on the mount member 3 with their upper surfaces faced to the mount member 3. The power MOS chip 5 (an example of the first semiconductor chip) includes a drain electrode 29 and a gate 31 formed in the upper surface and a source electrode 33 formed in the lower surface. The power MOS chip 7 (an example of the second semiconductor chip) on the other hand includes a drain electrode and a source electrode arranged in reverse order compared to the power MOS chip 5. In a word, the power MOS chip 7 includes a source electrode 35 and a gate 37 formed in the upper surface and a drain electrode 39 formed in the lower surface. An electrode 41 is formed on the upper surface of the driving IC chip 9.

The drain electrode 29 and the gate 31 of the power MOS chip 5, the source electrode 35 and the gate 37 of the power MOS chip 7, and the electrode 41 of the driving IC chip 9 are soldered on the mount member 3 via the bumps 19. Gaps between the chips 5, 7, 9 and the mount member 3 are filled with an underfill material 43.

An electrically conductive and thermally radiative member 45 is disposed to cover the lower surfaces of the power MOS chips 5, 7 and the driving IC chip 9. The member 45 comprises a single entirely flat plate composed of a metal such as copper and aluminum. The member 45 is soldered to the source electrode 33 on the lower surface of the power MOS chip 5 and the drain electrode 39 on the lower surface of the power MOS chip 7 via a conductive paste 47.

The electrically conductive and thermally radiative member 45 serves as a heat sink operative to radiate heat produced from the chips 5, 7 and 9 to external. The member 45 also has a function of electrically connecting the source electrode 33 of the power MOS chip 5 to the drain electrode 39 of the power MOS chip 7. The driving IC chip 9 is electrically insulated from the electrically conductive and thermally radiative member 45.

The member 45 is not always required to comprise a single entirely flat plate. For example, it may comprise a single plate with bends formed at the sides of the member 45. The plate is configured such that the bends are soldered via a conductive paste on the mount member 3 to lead out the potential between the source electrode 33 of the power MOS chip 5 and the drain electrode 39 of the power MOS chip 7 to the external terminal 13. In this way, the potential between the source electrode 33 of the power MOS chip 5 and the drain electrode 39 of the power MOS chip 7 can be led out to the external terminal 13 using the bends formed at the sides of the member 45. This configuration may reduce the advantage in easiness on fabrication of the semiconductor module as described later while it requires no connection of wiring from outside the semiconductor module 1 directly to the member 45. Therefore, the potential can be easily led out from the member 45 via the external terminal 13. The configuration to lead out the potential between the source electrode 33 of the power MOS chip 5 and the drain electrode 39 of the power MOS chip 7 to the external terminal 13 is not limited to one with the bends formed at the sides of the member 45. Rather, any configuration may be employed instead.

A resinous member 49 is disposed on the mount region 27 to seal the power MOS chips 5, 7 and the driving IC chip 9 in a single package. The electrically conductive and thermally radiative member 45 has one surface 51 facing the chips 5, 7, 9 and the other surface 53 opposite to the surface 51. The other surface 53 is exposed to external from the semiconductor module 1. In another structure, the electrically conductive and thermally radiative member 45 may be entirely covered in the resinous member 49 so as not to expose the electrically conductive and thermally radiative member 45 to external from the semiconductor module 1.

In this embodiment, as the power MOS chips 5, 7 and the driving IC chip 9 are fabricated in the single semiconductor module 1, the DC-DC converter incorporating the module 1 therein can be downsized. For further downsizing, in addition to the chips 5, 7 and 9, a capacitor or a coil may be fabricated in the single semiconductor module 1.

Structure of Power MOS Chip

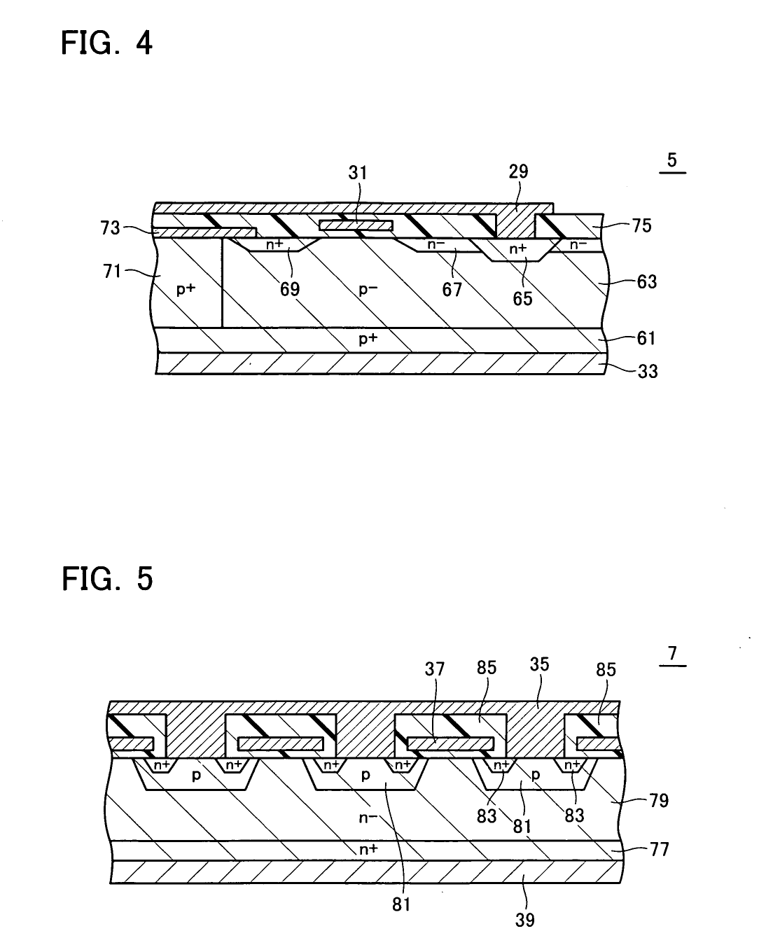

Structures of the power MOS chips 5 and 7 are described respectively. FIG. 4 is a cross-sectional view of part of the power MOS chip 5, or an example of the first semiconductor chip. The chip 5 comprises a p⁺-type silicon substrate 61 (an example of the first semiconductor substrate), and a p⁻-type base region 63 (an example of the first semiconductor region), or an epitaxial layer formed on the substrate. The silicon substrate 61 serves as a p⁺-type source region. The lower surface of the silicon substrate 61 is entirely made contact with the source electrode 33 (an example of the second main electrode).

The base region 63 includes an n⁺-type drain region 65 (an example of the second semiconductor region) and an adjacent n⁻-type drift region 67 both formed therein. The base region 63 also includes an n⁺-type source region 69 (an example of the third semiconductor region) formed therein and spaced from the drift region 67. A gate 31 is formed on a gate oxide film between the drift region 67 and the source region 69 to form a channel in the base region 63 under the gate 31. The drain region 65 is made conductive to the source region 69 through the channel and the drift region 67.

Adjacent to the source region 69, a p⁺-type conductive region 71 is formed, which passes through the base region 63 and reaches the silicon substrate 61. The conductive region 71 is electrically connected to the source region 69 via a short electrode 73 to short between the source region 69 and the base region 63.

An interlayer insulator 75 is formed to cover the gate 31 and the short electrode 73. The drain electrode 29 is formed on the interlayer insulator 75. The drain electrode 29 (an example of the first main electrode) is made contact with the drain region 65 through a contact hole formed through the interlayer insulator 75.

The power MOS chip 5 thus structured is of the so-called lateral type that causes current to flow in a direction parallel to the surface of the chip. In contrast, the power MOS chip 7 is of the so-called vertical type that causes current to flow in a direction normal to the surface of the chip. FIG. 5 is a cross-sectional view of part of the power MOS chip 7, or an example of the second semiconductor chip. The chip 7 comprises an n⁺-type silicon substrate 77 (an example of the second semiconductor substrate), and an n⁻-type drift region 79 (an example of the fourth semiconductor region), or an epitaxial layer formed on the substrate. The silicon substrate 77 serves as an n⁺-type drain region. The lower surface of the silicon substrate 77 is entirely made contact with the drain electrode 39 (an example of the second main electrode). The drift region 79 has a current path in a direction normal to the surface of the silicon substrate 77.

The drift region 79 includes a plurality of p-type base regions 81 (an example of the sixth semiconductor region) formed therein and spaced from each other. Each base region 81 includes n⁺-type source regions 83 (an example of the fifth semiconductor region) formed therein and spaced from each other. A gate 37 is formed on a gate oxide film between the base regions 81 to form a channel in the base region 81 under the gate 37. The source region 83 is made conductive to the drift region 79 through the channel.

An interlayer insulator 85 is formed to cover the gate 37. A source electrode 35 (an example of the first main electrode) is formed on the interlayer insulator 85. The source electrode 35 is made contact with the source region 83 and the base region 81 through a contact hole formed through the interlayer insulator 85.

Circuit Configuration and Operation of DC-DC Converter

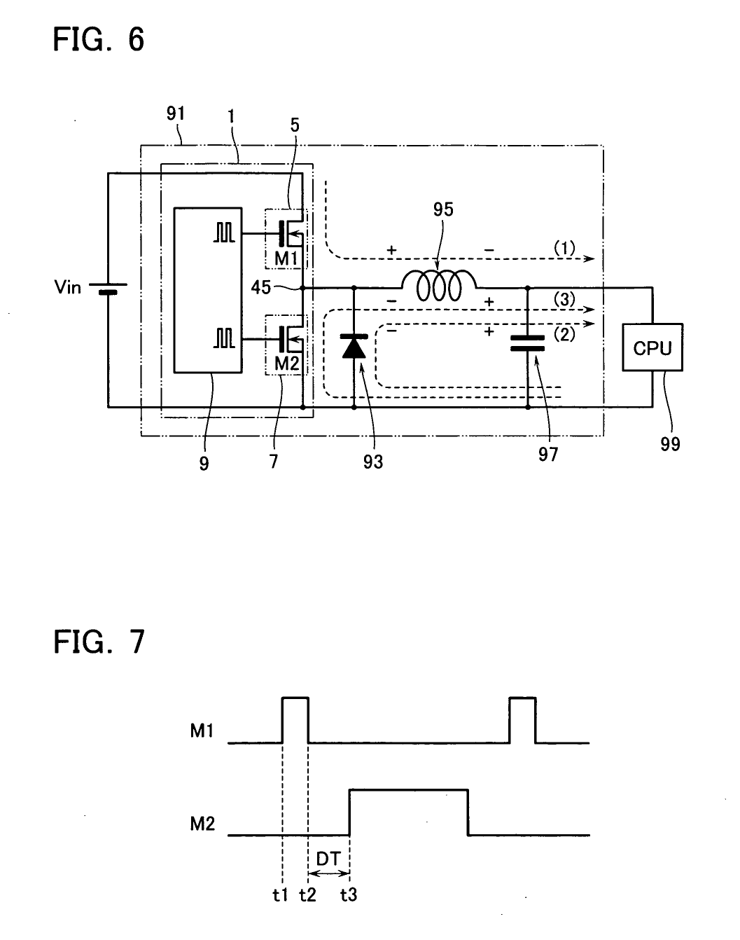

A circuit configuration and operation of the DC-DC converter including the semiconductor module 1 is described next. FIG. 6 is a circuit diagram of a DC-DC converter 91. The DC-DC converter 91 is of the synchronous rectifying non-insulated step-down type. This circuit is effective to reduce power losses and improve conversion efficiency.

The power MOS chip 5 (controlling element) at a higher potential side and the power MOS chip 7 (synchronous rectifying element) at a lower potential side each comprise an N-channel MOSFET with a low on-resistance and a low gate capacitance. The power MOS chip 7 is connected in parallel with a low-VF SBD (Schottky Barrier Diode) 93. The gate terminals of the power MOS chips 5 and 7 are connected to the gate-driving IC chip 9.

The chips 5 and 7 are normally driven under PWM control. The PWM control is a control method of stabilizing a DC output voltage from a switching power source. It varies a ratio of ON-time to OFF-time of a switching transistor (the power MOS chip 5) to control the output voltage. It elongates ON-time when the output voltage lowers and shortens it when the output voltage elevates to always retain a constant voltage.

An inductor 95 and a capacitor 97 are connected to the output stage of the DC-DC converter 91. A load such as a CPU 99 is connected across the output terminals of the DC-DC converter 91.

A basic operation of the DC-DC converter 91 is described next with reference to FIGS. 6 and 7. FIG. 7 is a timing chart of signals input to the power MOS chips 5 and 7. An input voltage Vin, for example, of 24 V is converted at the converter 91 to 1.5 V and supplied to the CPU 99.

The MOSFET (M1) in the power MOS chip 5 is turned on at time t1 while the MOSFET (M2) in the power MOS chip 7 stays off. As a result, a current flows under the input voltage Vin as shown by the arrow (1) to supply power to the CPU 99 via the inductor 95. Next, the MOSFET (M1) is turned off at time t2 to halt the supply of power to the CPU 99 under the input voltage Vin. Instead, power accumulated in the inductor 95 generates a current that commutates through the SBD 93 as shown by the arrow (2) to supply power to the CPU 99.

After elapse of a certain dead time DT set for prevention of passing through the MOSFET (M1) and the MOSFET (M2), the MOSFET (M2) is turned on at time t3. As the MOSFET (M2) is lower in resistance than the SBD 93, the power accumulated in the inductor 95 generates a current that commutates through the MOSFET (M2), not the SBD 93, as shown by the arrow (3) to supply power to the CPU 99. The capacitor 97 is employed to smooth the output voltage waveform.

Even without the use of the power MOS chip 7, or the MOSFET (M2), the DC-DC converter can function. The reason for providing the MOSFET (M2) is described next. The current shown by the arrow (2) flows through the SBD 93 at time t2. The current flowing in the SBD 93 causes a voltage drop, which produces a loss to the extent in power supplied to the CPU 99. The MOSFET may have a smaller voltage drop compared to the SBD. Then, current is allowed to flow via the SBD 93 during the dead time DT and via the MOSFET (M2) after elapse of the dead time DT to efficiently supply power to the CPU 99.

Main Effects of the Embodiment

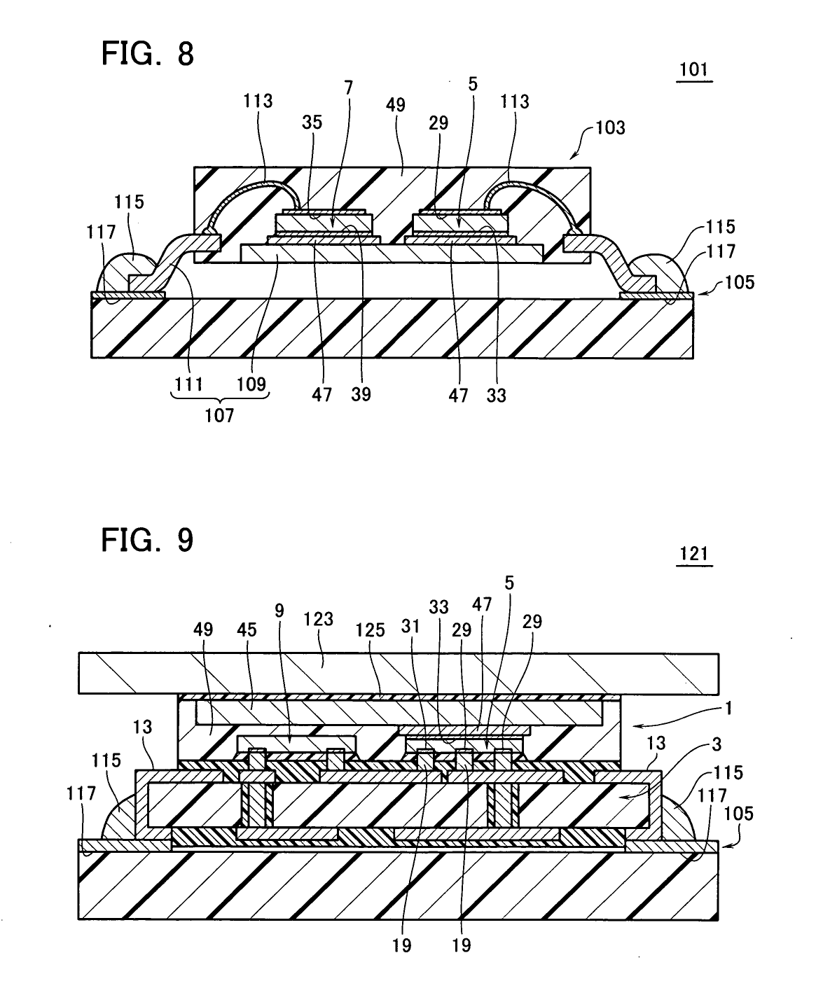

Main effects of the embodiment are described in comparison with a first and a second comparative examples. In accordance with the embodiment, the thermal radiation of the semiconductor module can be improved and the semiconductor module can be downsized more than the first comparative example. These features are described first. FIG. 8 is a cross-sectional view of a semiconductor device 101 according to the first comparative example. The semiconductor device 101 comprises a semiconductor module 103, and a mount board 105 provided to receive the semiconductor module 103 mounted thereon. The semiconductor module 103 includes the power MOS chips 5, 7 and the driving IC chip, not shown, all fabricated therein similar to the embodiment. Different from the embodiment, these chips are mounted on a lead frame 107 via wire bonding.

The semiconductor module 103 comprises the lead frame 107 including a die pad 109 and a lead 111; the power MOS chips 5, 7 and the driving IC chip (not shown) mounted on the die pad 109; and the resinous member 49 provided to seal these chips therein. These chips are fixed via the conductive paste 47, on the die pad 109 with the lower surfaces faced to the die pad 109. Therefore, the source electrode 33 formed on the lower surface of the power MOS chip 5 is electrically connected via the die pad 109 to the drain electrode 39 formed on the lower surface of the power MOS chip 7.

The drain electrode 29 formed on the upper surface of the power MOS chip 5 and the source electrode 35 formed on the upper surface of the power MOS chip 7 are connected via bonding wires 113 to the lead 111. The gates formed on the upper surfaces of the power MOS chip 5 and 7 are not represented in this section. The lead 111 is connected via solder 115 to an electrode 117 on the mount board 105.

FIG. 9 is a cross-sectional view of a semiconductor device 121 according to the embodiment. In the semiconductor device 121, the semiconductor module 1 is mounted on the mount board 105 with one surface faced to the mount board 105. The one surface is opposite to the other surface for use in arrangement of the electrically conductive and thermally radiative member 45. The semiconductor module 1 has a section corresponding to FIG. 3. The external terminal 13 on the semiconductor module 1 is connected to the electrode 117 via the solder 115.

A heat sink 123 of a flat plate type is disposed on the electrically conductive and thermally radiative member 45. It has a larger flat area than the member 45 has. The heat sink 123 is fixed on the electrically conductive and thermally radiative member 45 via an insulating adhesive 125.

The die pad 109 shown in FIG. 8 has the same functions as those of the electrically conductive and thermally radiative member 45 in FIG. 9. One is the function of electrically connecting the source electrode 33 on the lower surface of the power MOS chip 5 to the drain electrode 39 on the lower surface of the power MOS chip 7. Another is the function of radiating heat produced at these chips to external.

In the first comparative example shown in FIG. 8, the die pad 109 faces the mount board 105. Accordingly, heat radiated through the die pad 109 may easily accumulate in a space between the die pad 109 and the mount board 105. Therefore, a sufficient radiation effect can not be achieved depending on the case.

In the embodiment shown in FIG. 9, to the contrary, the electrically conductive and thermally radiative member 45 locates on the other surface of the mount board 105, remaining no obstacle to convection of heat. Therefore, heat from the chips 5, 7 and 9 can be radiated to external smoothly via the electrically conductive and thermally radiative member 45. Additionally, in the embodiment, the electrically conductive and thermally radiative member 45 covers the mount region 27 entirely, as shown in FIGS. 1-3, to improve the radiation effect.

Further, in the embodiment, the electrically conductive and thermally radiative member 45 locates on the other surface of the mount board 105, allowing the heat sink 123 to be disposed on the electrically conductive and thermally radiative member 45 to further improve the radiation effect. Additionally, in the embodiment, the heat sink 123 locates outside the semiconductor module 1. Accordingly, it is possible to expand the flat area of the heat sink 123 larger than that of the electrically conductive and thermally radiative member 45 to further improve the radiation effect. Thus, the radiation ability according to the embodiment can be improved compared to the first comparative example.

The semiconductor module 1 according to the embodiment can be downsized more than the semiconductor module 103 according to the first comparative example for the following reason. In the semiconductor module 103 according to the first comparative example, the chips 5 and 7 are mounted on the lead frame 107 via wire bonding. Therefore, the resinous member 49 for use in sealing the chips 5 and 7 has a relatively large thickness, which prevents downsizing of the semiconductor module 103.

In contrast, as shown in FIG. 2, the semiconductor module 1 has a thickness defined by a total of (a thickness of the mount member 3)+(a thickness of one of the chips 5 and 7)+(a thickness of the electrically conductive and thermally radiative member 45)+(a height of the bump 19)+(a thickness of the conductive paste 47). Accordingly, thinning these thicknesses can thin and downsize the semiconductor module 1. In a practical example, it is possible to achieve a thickness of 200 μm or less for the mount member 3, a thickness of 100 μm or less for the chip 5, 7, and a thickness of 200 μm or less for the electrically conductive and thermally radiative member 45. Thus, it is possible to achieve a thickness of 500 μm or less for the semiconductor module 1. As above, downsizing is easier for the embodiment than the first comparative example.

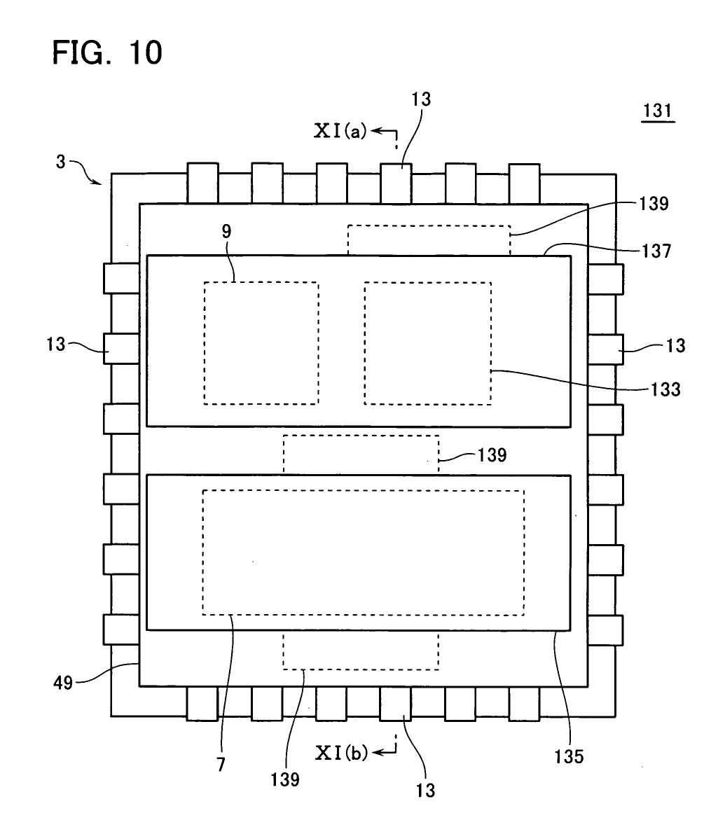

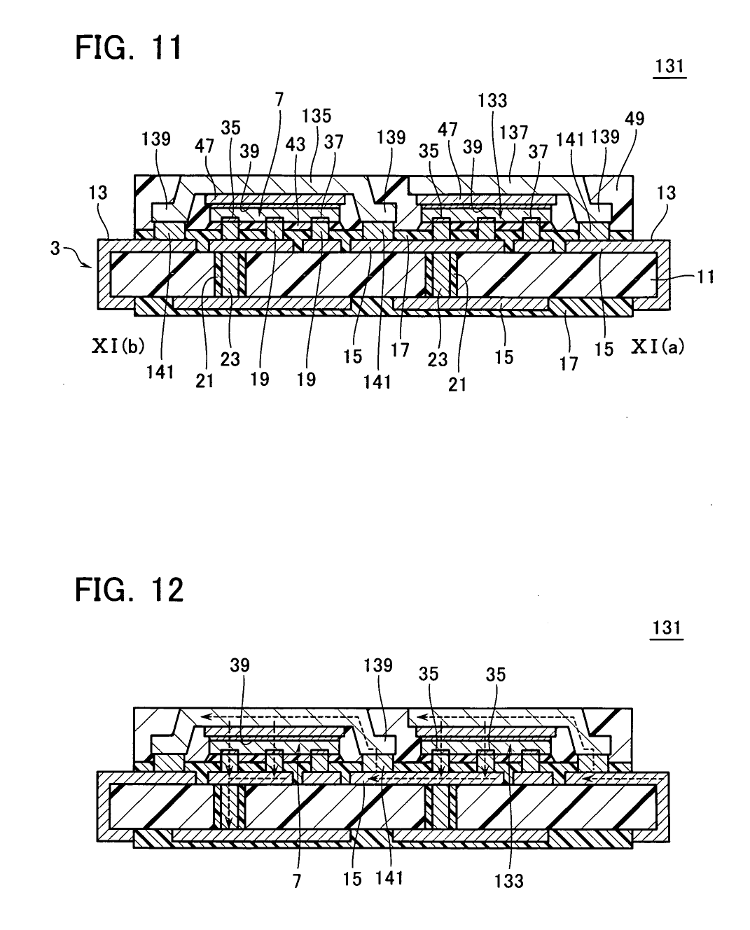

Effects of the embodiment are described next in comparison with the second comparative example. In accordance with the embodiment, it is possible to achieve lower impedance of the semiconductor module and easier fabrication of the semiconductor module than the second comparative example. FIGS. 10 and 11 are employed to describe the second comparative example first. FIG. 10 is a plan view of a semiconductor module 131 according to the second comparative example, which corresponds to FIG. 1. FIG. 11 is a cross-sectional view taken along XI(a)-XI(b) line in FIG. 10, which corresponds to FIG. 2.

The semiconductor module 131 according to the second comparative example differs from the semiconductor module 1 according to the embodiment in the following. A power MOS chip 133 of the second comparative example is located at a higher potential side, like the power MOS chip 5 of the embodiment except for the structure. The power MOS chip 133 is similarly structured as the power MOS chip 7 because the drain electrode 39 is formed on the lower surface of the chip and the source electrode 35 is formed on the upper surface of the chip as shown in FIG. 5.

The lower surfaces of the power MOS chips 7 and 133 can not be connected commonly because the lower surfaces are both employed to form the drain electrodes 39 therein. Therefore, plate-like electrically conductive and thermally radiative members 135 and 137 are disposed against the respective chips 7 and 133. Bends 139 are made at the sides of the members 135 and 137 and soldered on the mount member 3 via a conductive paste 141 to form a current path between the chips 7 and 133.

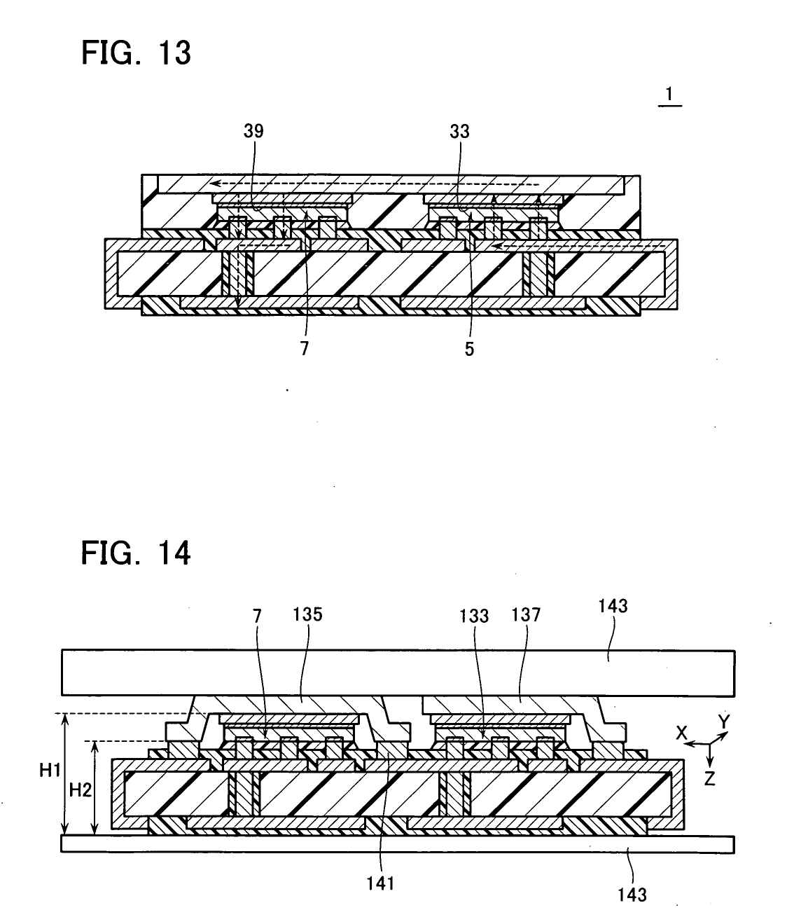

The following description is given to the reduction in impedance of the semiconductor module achieved in accordance with the embodiment over the second comparative example. FIG. 12 shows a current path in the semiconductor module 131 according to the second comparative example and corresponds to FIG. 11. FIG. 13 shows a current path in the semiconductor device 1 according to the embodiment and corresponds to FIG. 2. As shown in FIG. 12, the second comparative example requires a relatively longer current path to connect the source electrode 35 formed on the upper surface of the power MOS chip 133 to the drain electrode 39 formed on the lower surface of the power MOS chip 7. In addition, contacts are present between the bend 139 and the conductive paste 141 and between the wire 15 and the conductive paste 141.

In the embodiment shown in FIG. 13, a single plate, or the member 45, is employed to connect the source electrode 33 formed on the lower surface of the power MOS chip 5 to the drain electrode 39 formed on the lower surface of the power MOS chip 7. Thus, a shorter current path can achieved compared to the second comparative example. If the member 45 comprises a single entirely flat plate, the above contacts of the second comparative example are not present. Accordingly, the embodiment can reduce inductance and resistance in the current path over the second comparative example, resulting in reduced impedance of the semiconductor module. As a result, the DC-DC converter incorporating the semiconductor module 1 according to the embodiment can be improved so as to have a high efficiency.

The following description is given to the fabrication achieved easier in accordance with the embodiment than the second comparative example. As shown in FIG. 14, in the step of mounting the electrically conductive and thermally radiative members 135 and 137 according to the second comparative example, these members 135 and 137 are connected to the power MOS chips 7 and 133. In addition, they are connected to the conductive paste 141 on the wire 15 of the mount member 3. The connection to the conductive paste 141 requires accurate positioning of the electrically conductive and thermally radiative members 135 and 137 in X-Y directions.

The height H1 at the connection between the power MOS chip 7, 133 and the electrically conductive and thermally radiative member 135, 137 differs from the height H2 at the connection between the conductive paste 141 and the member 135, 137. Therefore, a height adjuster tool 143 is employed in a complicated manner to position the electrically conductive and thermally radiative members 135 and 137 in Z-direction. It is further required to arrange the electrically conductive and thermally radiative members 135 and 137 flat to thin the semiconductor module.

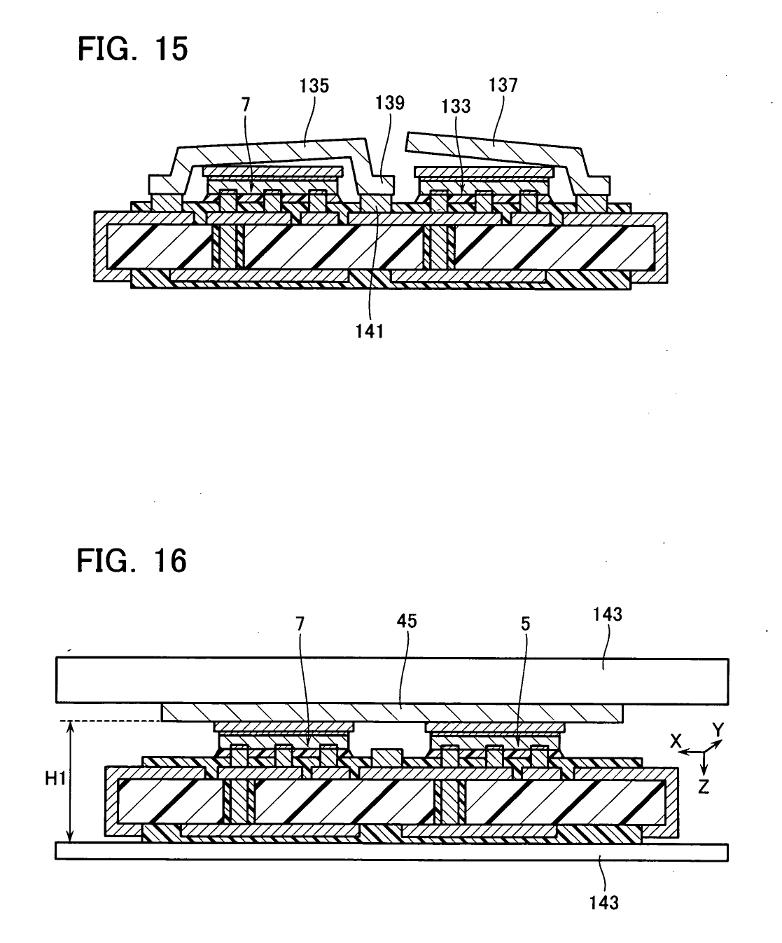

As above, in the second comparative example, when the electrically conductive and thermally radiative members 135 and 137 are mounted, positioning of the members 135 and 137 in X, Y and Z directions is required compatible with flat arrangement of the members 135 and 137. If such the compatibility can not be attained, the electrically conductive and thermally radiative members 135 and 137 are mounted obliquely as shown in FIG. 15, for example.

To the contrary, as shown in FIG. 16, in the step of mounting the electrically conductive and thermally radiative member 45 according to the embodiment, the member 45 is connected to the power MOS chips 5 and 7 only and is not connected to the conductive paste on the wire. Therefore, positioning of the electrically conductive and thermally radiative member 45 in X-Y directions requires no high accuracy. On positioning of the electrically conductive and thermally radiative member 45 in Z-direction, it is sufficient to only consider the height H1 at the connection between the power MOS chip 5, 7 and the electrically conductive and thermally radiative member 45. Accordingly, positioning in Z-direction and flat arrangement of the electrically conductive and thermally radiative member 45 can be achieved easily.

As described above, the embodiment achieves mounting of the electrically conductive and thermally radiative member easier than the second comparative example. Accordingly, fabrication of the semiconductor module 1 according to the embodiment is easy (in other words, the structure of the semiconductor module is suitable for mass production).

What is claimed is:

1. A semiconductor module, comprising:
a mount member;
a first semiconductor chip having an upper surface and a lower surface and mounted via flip chip bonding on said mount member with said upper surface faced to said mount member, said upper surface including a drain electrode and a gate formed therein, said lower surface including a source electrode formed therein;
a second semiconductor chip having an upper surface and a lower surface and mounted via flip chip bonding on said mount member with said upper surface faced to said mount member, said upper surface including a source electrode and a gate formed therein, said lower surface including a drain electrode formed therein;
an electrically conductive and thermally radiative member disposed to electrically connect said source electrode of said first semiconductor chip with said drain electrode of said second semiconductor chip and cover said lower surfaces of said semiconductor chips; and
a resinous member provided to seal said first and second semiconductor chips in a single package.

2. The semiconductor module according to claim 1, further comprising a driving IC chip mounted via flip chip bonding on said mount member to drive said gates of said first and second semiconductor chips,
wherein said resinous member seals said first and second semiconductor chips and said driving IC chip in a single package.

3. The semiconductor module according to claim 2, wherein said electrically conductive and thermally radiative member is insulated from said driving IC chip and covers said driving IC chip.

4. The semiconductor module according to claim 3, wherein said electrically conductive and thermally radiative member comprises a single plate that covers said first and second semiconductor chips and said driving IC chip.

5. The semiconductor module according to claim 1, wherein said mount member includes an external terminal region located at the rim thereof, and a mount region located more inwardly than said external terminal region,
said electrically conductive and thermally radiative member covering said mount region entirely.

6. The semiconductor module according to claim 1, wherein said electrically conductive and thermally radiative member has one surface and the other surface opposite thereto, said one surface facing said lower surfaces of said first and second semiconductor chips, said the other surface being exposed to external from said semiconductor module.

7. The semiconductor module according to claim 1, wherein said electrically conductive and thermally radiative member is entirely covered in said resinous member.

8. The semiconductor module according to claim 1, wherein said semiconductor module has a thickness defined by a total of (a thickness of said mount member)+(a thickness of one of said first and second semiconductor chips)+(a thickness of said electrically conductive and thermally radiative member)+(a height of a bump connecting said mount member with said one semiconductor chip)+(a thickness of a conductive paste connecting said one semiconductor chip with said electrically conductive and thermally radiative member).

9. The semiconductor module according to claim 1, wherein said first and second semiconductor chips comprise a power MOS chip each.

10. A semiconductor module, comprising:
a mount member;
a first and a second semiconductor chips each having an upper surface and a lower surface and mounted via flip chip bonding on said mount member with said upper surface faced to said mount member, said upper surface including a first main electrode and a gate formed therein, said lower surface including a second main electrode formed therein;
an electrically conductive and thermally radiative member disposed to electrically connect said second main electrode of said first semiconductor chip with said second main electrode of said second semiconductor chip and cover said lower surfaces of said semiconductor chips; and
a resinous member provided to seal said first and second semiconductor chips in a single package,
said first semiconductor chip including
a first semiconductor substrate of a first conduction type made contact with said second main electrode,
a first semiconductor region of said first conduction type located on said first semiconductor substrate,
a second semiconductor region of a second conduction type formed in said first semiconductor region and made contact with said first main electrode,
a third semiconductor region of said second conduction type formed in said first semiconductor region and made conductive to said second semiconductor region through a channel formed under said gate, and
a short electrode arranged to short between said first semiconductor region and said third semiconductor region,
said second semiconductor chip including
a second semiconductor substrate of said second conduction type made contact with said second main electrode,
a fourth semiconductor region of said second conduction type located on said second semiconductor substrate and having a current path in a direction normal to the surface of said second semiconductor substrate,
a fifth semiconductor region of said second conduction type made contact with said first main electrode, and
a sixth semiconductor region of said first conduction type, in which a channel is formed under said gate to make said fourth semiconductor region conductive to said fifth semiconductor region therethrough.

11. The semiconductor module according to claim 10, further comprising a driving IC chip mounted via flip chip bonding on said mount member to drive said gates of said first and second semiconductor chips,
wherein said resinous member seals said first and second semiconductor chips and said driving IC chip in a single package.

12. The semiconductor module according to claim 11, wherein said electrically conductive and thermally radiative member is insulated from said driving IC chip and covers said driving IC chip.

13. The semiconductor module according to claim 12, wherein said electrically conductive and thermally radiative member comprises a single plate that covers said first and second semiconductor chips and said driving IC chip.

14. The semiconductor module according to claim 10, wherein said mount member includes an external terminal region located at the rim thereof, and a mount region located more inwardly than said external terminal region,
said electrically conductive and thermally radiative member covering said mount region entirely.

15. The semiconductor module according to claim 10, wherein said electrically conductive and thermally radiative member has one surface and the other surface opposite thereto, said one surface facing said lower surfaces of said first and second semiconductor chips, said the other surface being exposed to external from said semiconductor module.

16. The semiconductor module according to claim 10, wherein said electrically conductive and thermally radiative member is entirely covered in said resinous member.

17. The semiconductor module according to claim 10, wherein said semiconductor module has a thickness defined by a total of (a thickness of said mount member)+(a thickness of one of said first and second semiconductor chips)+(a thickness of said electrically conductive and thermally radiative member)+(a height of a bump connecting said mount member with said one semiconductor chip)+(a thickness of a conductive paste connecting said one semiconductor chip with said electrically conductive and thermally radiative member).

18. The semiconductor module according to claim 10, wherein said first and second semiconductor chips comprise a power MOS chip each.

19. A semiconductor device, comprising:
a semiconductor module including
a mount member,
a first semiconductor chip having an upper surface and a lower surface and mounted via flip chip bonding on said mount member with said upper surface faced to said mount member, said upper surface including a drain electrode and a gate formed therein, said lower surface including a source electrode formed therein,
a second semiconductor chip having an upper surface and a lower surface and mounted via flip chip bonding on said mount member with said upper surface faced to said mount member, said upper surface including a source electrode and a gate formed therein, said lower surface including a drain electrode formed therein,
an electrically conductive and thermally radiative member disposed to electrically connect said source electrode of said first semiconductor chip with said drain electrode of said second semiconductor chip and cover said lower surfaces of said semiconductor chips, and
a resinous member provided to seal said first and second semiconductor chips in a single package;
amount board provided to receive said semiconductor module mounted thereon with one surface faced to said mount board, said one surface being opposite to the other surface used in arrangement of said electrically conductive and thermally radiative member; and
a heat sink having a larger flat area than said electrically conductive and thermally radiative member and insulated from and disposed on said electrically conductive and thermally radiative member.
